(19) United States
(12) Patent Application Publication
(10) Pub. No.: US 2013/0074917 A1
(43) Pub. Date: Mar. 28, 2013

(54) PROCESS FOR THE PRODUCTION OF A MWT SILICON SOLAR CELL

(71) Applicants: Kenneth Warren Hang, Cary, NC (US); Giovanna Laudisio, Bristol (GB); John McKean Oleksyn, Bristol (GB); Jason Kenneth Parsons, Bristol (GB); Rosalynne Sophie Watt, Bristol (GB)

(72) Inventors: Kenneth Warren Hang, Cary, NC (US); Giovanna Laudisio, Bristol (GB); John McKean Oleksyn, Bristol (GB); Jason Kenneth Parsons, Bristol (GB); Rosalynne Sophie Watt, Bristol (GB)

(73) Assignee: E. I. DU PONT DE NEMOURS AND COMPANY, Wilmington (DE)

(21) Appl. No.: 13/428,434

(22) Filed: Mar. 23, 2012

Related U.S. Application Data
(60) Provisional application No. 61/467,077, filed on Mar. 24, 2011.

(51) Int. Cl. H01L 31/18; H01L 31/0224

(52) U.S. Cl. CPC H01L 31/18; H01L 31/022425
USPC 136/256; 438/98

(57) ABSTRACT

A process for the production of a MWT silicon solar cell, wherein a conductive metal paste with no or only poor fire-through capability is applied, dried and fired to form a continuous metallization comprising a top set of conductive metal collector lines and a metallization of the inside of the holes of an n-type MWT silicon solar cell wafer, wherein the top set of conductive metal collector lines superimposes a bottom set of conductive metal collector lines on the front-side of the n-type MWT silicon solar cell wafer, said bottom set of conductive metal collector lines having no contact with the inside of the holes.

### FIELD OF THE INVENTION

The present invention is directed to a process for the production of a MWT (metal-wrap-through) silicon solar cell having an n-type silicon base. The present invention is also directed to the respective MWT silicon solar cells.

### TECHNICAL BACKGROUND OF THE INVENTION

The majority of the solar cells currently produced are based upon crystalline silicon.

A conventional solar cell with a p-type (p-doped) silicon base has an n-type (n-doped) emitter in the form of an n-type diffusion layer on its front-side. Such conventional silicon solar cell structure uses a negative electrode to contact the front-side or sun side of the cell, and a positive electrode on the back-side. It is well known that radiation of an appropriate wavelength falling on a p-n junction of a semiconductor body serves as a source of external energy to generate electron-hole pairs in that body. The potential difference that exists at a p-n junction, causes holes and electrons to move across the junction in opposite directions, thereby giving rise to flow of an electric current that is capable of delivering power to an external circuit. Most solar cells are in the form of a silicon wafer that has been metallized, i.e., provided with metal contacts which are electrically conductive. Typically, the front-side metallization is in the form of a so-called H pattern, i.e. in the form of a silver grid cathode comprising thin parallel finger lines (collector lines) and busbars intersecting the finger lines at right angle, whereas the back-side metallization is an aluminum anode in electric connection with silver or silver/aluminum busbars or tabs. The photoelectric current is collected from the front-side busbars and the back-side busbars or tabs.

Alternatively, a reverse solar cell structure with an n-type silicon base is also known. Such cells have a front p-type silicon surface (front p-type emitter) with a positive electrode on the front-side and a negative electrode to contact the back-side of the cell. Solar cells with n-type silicon bases (n-type silicon solar cells) can in theory produce absolute efficiency gains of up to 1% compared to solar cells with p-type silicon bases owing to the reduced recombination velocity of electrons in the n-doped silicon.

### SUMMARY OF THE INVENTION

The present invention relates to a process for the production of a MWT silicon solar cell having an n-type silicon base. The process comprises the steps:
(1) providing an n-type silicon wafer with (i) holes forming vias between the front-side and the back-side of the wafer, (ii) a p-type emitter extending over the entire front-side and the inside of the holes, (iii) an ARC layer on the front-side that leaves out the inside of the holes, and (iv) a front-side metallization in the form of a bottom set of thin conductive metal collector lines, said bottom set of thin conductive metal collector lines having no contact with the inside of the holes,
(2) applying a conductive metal paste over said bottom set of thin conductive metal collector lines and to the holes of the silicon wafer to form a continuous metallization which comprises a top set of thin conductive metal collector lines and a metallization of the inside of the holes,
(3) drying the applied conductive metal paste, and
(4) firing the dried conductive metal paste, whereby the wafer reaches a peak temperature of 700 to 900° C.,
wherein the top set of thin conductive metal collector lines superimposes the bottom set of thin conductive metal collector lines,
wherein the conductive metal paste has no or only poor fire-through capability and comprises (a) at least one particulate electrically conductive metal selected from the group consisting of silver, copper and nickel, and (b) an organic vehicle. Accordingly, the present invention relates also to the so produced MWT silicon solar cells.

### DETAILED DESCRIPTION OF THE INVENTION

The term “continuous metallization” used herein means that the top set of thin conductive metal collector lines and the metallization of the inside of the holes form one continuous or, in other words, uninterrupted entity and, as a consequence, that the top set of thin conductive metal collector lines is in direct electric contact with the metallization of the inside of the holes.

MWT silicon solar cells are examples of silicon solar cells having another cell design than the silicon solar cells described in the section “TECHNICAL BACKGROUND OF THE INVENTION”. MWT silicon solar cells are well-known to the skilled person (cf. for example, the website “http://www.sollandsolar.com/IManager/Content/4680/qfl7/mt1537/mi3099 4/mu1254913665/mv2341” and the leaflet “Preliminary Datasheet Sunweb” which can be downloaded from that website and F. Clement et al., “Industrially feasible multi-crystalline metal wrap through (MWT) silicon solar cells exceeding 16% efficiency”, Solar Energy Materials & Solar Cells 93 (2009), pages 1051-1055). MWT silicon solar cells represent a special type of silicon solar cells; they are back contact cells allowing for less front-side shadowing than standard silicon solar cells.

Just like in case of the standard silicon solar cells mentioned above, MWT silicon solar cells can be produced as MWT silicon solar cells having a p-type silicon base or, in the alternative, as MWT silicon solar cells having an n-type silicon base.

The silicon wafers of MWT silicon solar cells with an n-type silicon base are provided with small holes forming vias between the front- and the back-side of the cell. MWT silicon solar cells having an n-type silicon base have a p-type emitter extending over the entire front-side and the inside of the holes. The p-type emitter is covered with a dielectric passivation layer which serves as an ARC (antireflective coating) layer, as is conventional for silicon solar cells. Whereas the p-type emitter extends not only over the entire front-side but also over the inside of the holes, the dielectric passivation layer does not and leaves out the inside of the holes and, optionally, also a narrow rim around the front-edges of the holes. The inside of the holes and, if present, the narrow rim around the front-edges of the holes, i.e. the p-type diffusion layer not covered with the dielectric passivation layer, is provided with a metallization either in the form of a conductive metal layer (open hole) or in the form of a conductive metal plug (hole filled with conductive metal). The metallizations of the holes are typically applied from one or two conductive metal pastes and fired. To avoid misunderstandings, if two different conductive metal pastes are used, they are not applied so as to form a double-layer metallization; rather, one conductive metal paste is applied to the holes from the front-side thereof and the other from the back-side. The metallizations of the holes serve as emitter contacts and form anodic back contacts of the MWT silicon solar cell. In addition, the front-side of the MWT silicon solar cell is provided with a front-side metallization in the form of thin conductive metal collector lines which are arranged in a pattern typical for MWT silicon solar cells, for-example, in a grid- or web-like pattern or as thin parallel finger lines. The term “pattern typical for MWT silicon solar cells” means that the terminals of the collector lines overlap with the metallizations of the holes and are thus electrically connected therewith. The collector lines are applied from a conductive metal paste having fire-through capability. After drying the collector lines so applied they are fired through the front-side dielectric passivation layer thus making contact with the front surface of the silicon substrate.

The term “metal paste having fire-through capability” used in the description and the claims means a metal paste which etches and penetrates through (fires through) a passivation or ARC layer during firing thus making electrical contact with the surface of the silicon substrate. It is also true, that a metal paste having poor or even no fire-through capability behaves contrarily; it does not fire through a passivation or ARC layer and makes no electrical contact with the silicon substrate upon firing. To avoid misunderstandings; in this context the term “no electrical contact” shall not be understood absolute; rather, it shall mean that the contact resistivity between fired metal paste and silicon surface exceeds 1Ω·cm², whereas, in case of electrical contact, the contact resistivity between fired metal paste and silicon surface is in the range of 1 to 10 mΩ·cm².

The contact resistivity can be measured by TLM (transfer length method). To this end, the following procedure of sample preparation and measurement may be used: A silicon wafer having an ARC or passivation layer (for example, a 75 nm thick SiNₓ layer) is screen printed on that layer with the metal paste to be tested in a pattern of parallel lines (for example, 127 μm wide and 6 μm thick lines with a spacing of 2.2 mm between the lines) and is then fired with the wafer reaching a peak temperature of, for example, 800° C. The fired wafer is laser-cutted into 10 mm by 28 mm long strips, where the parallel lines do not touch each other and at least 6 lines are included. The strips are then subject to conventional TLM measurement at 20° C. in the dark. The TLM measurement can be carried out using the device GP 4-Test Pro from GP Solar.

The back-side of a MWT silicon solar cell having an n-type silicon base is provided with cathodic conductive metal collector back contacts, which are in any case electrically insulated from the metallizations of the holes. The photoelectric current is collected from the anodic back contacts and the cathodic conductive metal collector back contacts of the MWT silicon solar cell.

Similar to the production of a silicon solar cell of the reverse type mentioned above, the production of a MWT silicon solar cell having an n-type silicon base starts with the formation of an n-type silicon substrate in the form of a silicon wafer. To this end, an n-doped base is typically formed via thermal diffusion of a phosphorus containing precursor such as POCl₃ into the silicon wafer. Typically, the silicon wafers have a thickness in the range of, for example, 140 to 220 μm and an area in the range of, for example, 150 to 400 cm². Small holes forming vias between the front- and the back-side of the wafer are applied, typically by laser drilling. The holes so produced are, for example, 30 to 250 μm in diameter, and they are evenly distributed over the wafer. Their number lies in the range of, for example, 10 to 100 per wafer. Then a p-type diffusion layer is formed, typically via thermal diffusion of a boron containing precursor such as BBr₃. The p-type diffusion layer is formed over the entire front-surface of the silicon substrate including the inside of the holes. The p-n junction is formed where the concentration of the n-type dopant equals the concentration of the p-type dopant. The cells having the p-n junction close to the sun side, have a junction depth between 50 and 500 nm.

After formation of the diffusion layer, excess surface glass is removed from the emitter surface by etching, in particular, in a strong acid like, for example, hydrofluoric acid. Typically, a dielectric layer, for example, of TiOₓ, SiOₓ, TiOₓ/SiOₓ, or, in the form of a dielectric stack of SiNₓ/SiOₓ or, in particular, of SiNₓ is then formed on the front-side p-type diffusion layer leaving out however the inside of the holes and, optionally, also a narrow rim around the front edges of the holes. Deposition of the dielectric may be performed, for example, using a process such as plasma CVD (chemical vapor deposition) in the presence of hydrogen or sputtering. The dielectric layer serves as both an ARC and passivation layer for the front-side of the MWT silicon solar cell.

Just like a conventional solar cell structure with an n-type base, MWT silicon solar cells having an n-type base typically have a positive electrode on their front-side and a negative electrode on their back-side. The positive front electrode takes the form of thin conductive collector lines arranged in a pattern typical for MWT silicon solar cells. The thin conductive collector lines are typically applied by screen printing, drying and firing a front-side conductive metal paste (front electrode forming conductive metal paste) on the ARC layer on the front-side of the cell, whereby the terminals of the collector lines overlap with the metallizations of the holes to enable electric connection therewith. Firing is typically carried out in a belt furnace for a period of 1 to 5 minutes with the wafer reaching a peak temperature in the range of 700 to 900° C.

As already mentioned, the holes of the silicon wafers of the MWT silicon solar cells are provided with metallizations. To this end, the holes themselves are metallized by applying conductive metal paste to the holes, either in the form of a conductive metal layer (open holes) or in the form of conductive metal plugs (holes filled with conductive metal). The metallizations may cover only the inside of the holes or also a narrow rim around the edges of the holes, whereby the narrow rim may be present on the front edges of the holes, on the back-side edges of the holes or on both. The metallizations may be applied from one single conductive metal paste. It is also possible to apply the metallizations from two different conductive metal pastes, i.e. one conductive metal paste may be applied to the front-side of the holes and the other to their back-side. After application of the one or two conductive metal pastes it is/they are dried and fired to form emitter contacts and, respectively, anodic back contacts of the MWT silicon solar cell. Firing is typically carried out in a belt furnace for a period of 1 to 5 minutes with the wafer reaching a peak temperature in the range of 700 to 900° C. The fired metallizations of the holes are in electric connection with the terminals of the thin front-side conductive collector lines.

In addition, a back-side silver paste is applied, typically screen printed, and successively dried on the back-side of the n-type silicon substrate avoiding any contact with the metallizations of the holes. In other words, the back-side silver paste is applied ensuring that it stays electrically insulated from the metallizations of the holes prior to as well as after firing. The back-side silver paste is applied evenly distributed over the back-side of the n-type silicon substrate. The dried back-side silver paste is then transformed by firing to become evenly distributed cathodic silver back collector contacts. Firing is typically carried out in a belt furnace for a period of 1 to 5 minutes with the wafer reaching a peak temperature in the range of 700 to 900° C. The front anode, the metallizations of the holes and the back cathodes can be fired sequentially or cofired. The silver back collector contacts account only for a small area of the back-side of the n-type silicon substrate. In addition, the front-side conductive metal paste applied as thin collector lines fires through the ARC layer during firing, and is thereby able to electrically contact the front-side p-type emitter.

The process of the present invention allows for the production of MWT silicon solar cells having a front-side metallization, a portion of said front-side metallization being two-layered. Moreover, the process of the present invention allows for simultaneously forming the second layer of the two-layer portion of the front-side metallization and the metallization of the inside of the holes of MWT silicon solar cells, wherein said second layer of the two-layer portion and the metallization of the inside of the holes belong to or even form a continuous metallization. The fired conductive metal paste adheres well to the holes, i.e. it adheres well to the p-type emitter surface of the inside of the holes of the silicon wafer. Good adhesion is important with regard to a long service life of the MWT silicon solar cells.

Without being bound to theory it is believed that the conductive metal paste with its at best poor fire-through capability does not or not significantly damage the p-type emitter when steps (3) and (4) of the process of the present invention are carried out. It is important to avoid or reduce damage of the p-type emitter to avoid shunting characteristics.

In step (1) of the process of the present invention an n-type silicon wafer is provided. The silicon wafer has (i) holes forming vias between the front-side and the back-side of the wafer, (ii) a p-type emitter extending over the entire front-side and the inside of the holes, (iii) an ARC layer on the front-side that leaves out the inside of the holes, and (iv) a front-side metallization in the form of a bottom set of thin conductive metal collector lines, said bottom set of thin conductive metal collector lines having no contact with the inside of the holes.

The silicon wafer is a mono or polycrystalline silicon wafer as is conventionally used for the production of MWT silicon solar cells; it has both a p-type region, an n-type region, and a p-n junction. The silicon wafer has an ARC layer on its front-side, for example, of TiOₓ, SiOₓ, TiOₓ/SiOₓ, or, in the form of a dielectric stack of SiNₓ/SiOₓ or, in particular, of SiNₓ. The ARC layer leaves out the inside of the holes and, optionally, also a narrow rim around the front edges of the holes. Such silicon wafers are well known to the skilled person; for brevity reasons reference is expressly made to the disclosure above.

The silicon wafer is already provided with a front-side metallization in the form of a bottom set of thin conductive metal collector lines. Said bottom set of thin conductive metal collector lines has no contact (and thus also no electric contact) with the inside of the holes. In case the holes have narrow rims around their front edges left out by the ARC layer, the bottom set of thin conductive metal collector lines has also no contact with such rims. In other words, in any case, the bottom set of thin conductive metal collector lines does not extend beyond the area covered by the ARC layer.

The thin conductive metal collector lines of the bottom set have a width of, for example, 50 to 150 μm and a dry layer thickness of, for example, 10 to 40 μm. They are arranged in a grid- or web-like pattern or form an arrangement of parallel lines and they cover, or, more precisely, they shadow an area percentage of the front-side ARC layer of, for example, 8 to 20% in total.

The bottom set of thin conductive metal collector lines is typically applied from a conventional conductive metal paste having fire-through capability, in particular, a silver paste having fire-through capability. Such conductive metal pastes or silver pastes with fire-trough capability are commercially available, for example, from DuPont. It may be advantageous if the conductive metal paste having fire-through capability comprises at least one particulate p-type dopant selected from the group consisting of boron, aluminum and p-type silicon alloys selected from the group consisting of alloys comprising silicon and boron, alloys comprising silicon and aluminum and alloys comprising silicon, boron and aluminum. The term “p-type silicon alloy” used herein means a silicon alloy of the p-type, i.e. the proportion of boron and/or aluminum in such silicon alloy is sufficiently high to ensure the silicon alloy has a p-type character. The total content of the at least one p-type dopant in the conductive metal paste may be, for example, 0.5 to 10 wt.-%, or, in an embodiment, 1 to 5 wt.-%, or, in particular 1.5 to 3 wt.-%.

The method of application of the conductive metal paste having fire-through capability may be any of the conventional application methods known to the skilled person, for example, printing, in particular, screen-printing, in each case followed by firing the dried conductive metal paste, which in the course of the firing process fires through the ARC layer. Insofar, the formation of the bottom set of thin conductive metal collector lines is performed using conventional standard techniques known to the person skilled in the art of providing silicon solar cell wafers with metallizations.

The silicon wafer may also already be provided with the cathodic silver back collector contacts, as described above.

In step (2) of the process of the present invention a conductive metal paste having no or only poor fire-through capability and comprising (a) at least one particulate electrically conductive metal selected from the group consisting of silver, copper and nickel, and (b) an organic vehicle is applied over said bottom set of thin conductive metal collector lines and to the holes of the silicon wafer to form a continuous metallization.

The application over the bottom set of thin conductive metal collector lines and to the holes of the silicon wafer is preferably simultaneously performed, i.e. preferably in one single step. The continuous metallization comprises a top set of thin conductive metal collector lines and a metallization of the inside of the holes. In an embodiment, the continuous metallization consists of a top set of thin conductive metal collector lines and a metallization of the inside of the holes. In any case, the top set of thin conductive metal collector lines superimposes the bottom set of thin conductive metal collector lines, i.e. said bottom set and said top set are congruent to each other, or in other words, the thin conductive metal collector lines of the top set are arranged in the same grid- or web-like pattern or form the same arrangement of parallel lines as the thin conductive metal collector lines of the bottom set.

In a particular embodiment of the process of the present invention, the conductive metal paste comprises as component (c) at least one glass frit selected from the group consisting of (i) lead-free glass frits with a softening point temperature in the range of 550 to 611° C. and containing 11 to 33 wt. % (weight-%) of SiO2, >0 to 7 wt. %, in particular, 5 to 6 wt. % of Al₂O₃ and 2 to 10 wt. % of B₂O₃ and (ii) lead-containing glass frits with a softening point temperature in the range of 571 to 636° C. and containing 53 to 57 wt. % of PbO, 25 to 29 wt. % of SiO₂, 2 to 6 wt. % of Al₂O₃ and 6 to 9 wt. % of B₂O₃.

The term “softening point temperature” is used herein. It shall mean the glass transition temperature, determined by differential thermal analysis DTA at a heating rate of 10 K/min.

The conductive metal paste comprises at least one particulate electrically conductive metal selected from the group consisting of silver, copper and nickel. Preferably, the particulate electrically conductive metal is silver. The particulate silver may be comprised of silver or a silver alloy with one or more other metals like, for example, copper. In case of silver alloys the silver content is, for example, 99.7 to below 100 wt. %. The particulate electrically conductive metal or silver may be uncoated or at least partially coated with a surfactant. The surfactant may be selected from, but is not limited to, stearic acid, palmitic acid, lauric acid, oleic acid, capric acid, myristic acid and linolic acid and salts thereof, for example, ammonium, sodium or potassium salts.

The average particle size of the particulate electrically conductive metal or silver is in the range of, for example, 0.5 to 20 μm, or, in an embodiment, for example, 0.5 to 5 μm. The particulate electrically conductive metal or silver may be present in the conductive metal paste in a proportion of 50 to 92 wt. %, or, in an embodiment, 65 to 84 wt. %, based on total conductive metal paste composition.

The term “average particle size” is used herein. It shall mean the average particle size (mean particle diameter, d50) determined by means of laser scattering.

All statements made herein in relation to average particle sizes relate to average particle sizes of the relevant materials as are present in the conductive metal paste composition.

It is possible to replace a small proportion of the electrically conductive metal selected from the group consisting of silver, copper and nickel by one or more other particulate metals. The proportion of such other particulate metal(s) is, for example, 0 to 30 wt. %, or, in an embodiment, for example, 0 to 10 wt. %, based on the total of particulate metals contained in the conductive metal paste.

The conductive metal paste comprises an organic vehicle. A wide variety of inert viscous materials can be used as organic vehicle. The organic vehicle may be one in which the particulate constituents (particulate metal, glass frit, further optionally present inorganic particulate constituents) are dispersible with an adequate degree of stability. The properties, in particular, the rheological properties, of the organic vehicle may be such that they lend good application properties to the conductive metal paste composition, including: stable dispersion of insoluble solids, appropriate rheology for application, appropriate wettability of the paste solids, a good drying rate, and good firing properties. The organic vehicle used in the conductive metal paste may be a nonaqueous inert liquid. The organic vehicle may be an organic solvent or an organic solvent mixture; in an embodiment, the organic vehicle may be a solution of organic polymer(s) in organic solvent(s). In an embodiment, the polymer used for this purpose may be ethyl cellulose. Other examples of polymers which may be used alone or in combination include ethylhydroxyethyl cellulose, wood rosin, phenolic resins and poly(meth)acrylates of lower alcohols. Examples of suitable organic solvents comprise ester alcohols and terpenes such as alpha- or beta-terpineol or mixtures thereof with other solvents such as kerosene, dibutylphthalate, diethylene glycol butyl ether, diethylene glycol butyl ether acetate, hexylene glycol and high boiling alcohols. In addition, volatile organic solvents for promoting rapid hardening after application of the conductive metal paste in step (2) of the process of the present invention can be included in the organic vehicle. Various combinations of these and other solvents may be formulated to obtain the viscosity and volatility requirements desired.

The organic vehicle content in the conductive metal paste may be dependent on the method of applying the paste and the kind of organic vehicle used, and it can vary. In an embodiment, it may be from 10 to 45 wt. %, or, in an embodiment, it may be in the range of 12 to 35 wt. %, based on total conductive metal paste composition. The number of 10 to 45 wt. % includes organic solvent(s), possible organic polymer(s) and possible organic additive(s).

The organic solvent content in the conductive metal paste may be in the range of 5 to 25 wt. %, or, in an embodiment, 10 to 20 wt. %, based on total conductive metal paste composition.

The organic polymer(s) may be present in the organic vehicle in a proportion in the range of 0 to 20 wt. %, or, in an embodiment, 5 to 10 wt. %, based on total conductive metal paste composition.

In the particular embodiment of the process of the present invention, the conductive metal paste comprises at least one glass frit selected from the group consisting of (i) lead-free glass frits with a softening point temperature in the range of 550 to 611° C. and containing 11 to 33 wt. % of SiO₂, >0 to 7 wt. %, in particular, 5 to 6 wt. % of Al₂O₃ and 2 to 10 wt. % of B₂O₃ and (ii) lead-containing glass frits with a softening point temperature in the range of 571 to 636° C. and containing 53 to 57 wt. % of PbO, 25 to 29 wt. % of SiO₂, 2 to 6 wt. % of Al₂O₃ and 6 to 9 wt. % of B₂O₃.

In case of the lead-free glass frits of type (i), the weight percentages of SiO₂, Al₂O₃ and B₂O₃ do not total 100 wt.-% and the missing wt.-% are in particular contributed by one or more other oxides, for example, alkali metal oxides like Na₂O, alkaline earth metal oxides like MgO and metal oxides like Bi₂O₃, TiO₂ and ZnO. The lead-free glass frits of type (i) may contain 40 to 73 wt.-%, in particular 48 to 73 wt.-% of Bi₂O₃. The weight percentages of Bi₂O₃, SiO₂, Al₂O₃ and B₂O₃ may or may not total 100 wt.-%. In case they do not total 100 wt.-% the missing wt.-% may in particular be contributed by one or more other oxides, for example, alkali metal oxides like Na₂O, alkaline earth metal oxides like MgO and metal oxides like TiO₂ and ZnO.

In case of the lead-containing glass frits of type (ii), the weight percentages of PbO, SiO₂, Al₂O₃ and B₂O₃ may or may not total 100 wt.-%. In case they do not total 100 wt.-% the missing wt.-% may in particular be contributed by one or more other oxides, for example, alkali metal oxides like Na₂O, alkaline earth metal oxides like MgO and metal oxides like TiO₂ and ZnO.

In case the conductive metal paste comprises lead-free glass frit of type (i) as well as lead-containing glass frit of type (ii), the ratio between both glass frit types may be any or, in other words, in the range of from >0 to infinity. Preferably, the conductive metal paste as used in the particular embodiment of the process of the present invention comprises no glass frit other than glass frit of type (i) and/or type (ii).

The one or more glass frits selected from the groups (i) and/or (ii) serve as inorganic binder. The average particle size of the glass frit(s) is in the range of, for example, 0.5 to 4 μm. The total content of glass frit selected from the groups (i) and/or (ii) in the conductive metal paste as used in the particular embodiment of the process of the present invention is, for example, 0.25 to 8 wt. %, or, in an embodiment, 0.8 to 3.5 wt. %.

The preparation of the glass frits is well known and consists, for example, in melting together the constituents of the glass, in particular in the form of the oxides of the constituents, and pouring such molten composition into water to form the frit. As is well known in the art, heating may be conducted to a peak temperature in the range of, for example, 1050 to 1250° C. and for a time such that the melt becomes entirely liquid and homogeneous, typically, 0.5 to 1.5 hours.

The glass may be milled in a ball mill with water or inert low viscosity, low boiling point organic liquid to reduce the particle size of the frit and to obtain a frit of substantially uniform size. It may then be settled in water or said organic liquid to separate fines and the supernatant fluid containing the fines may be removed. Other methods of classification may be used as well.

The conductive metal paste may comprise one or more organic additives, for example, surfactants, thickeners, rheology modifiers and stabilizers. The organic additive(s) may be part of the organic vehicle. However, it is also possible to add the organic additive(s) separately when preparing the conductive metal paste. The organic additive(s) may be present in the conductive metal paste in a total proportion of, for example, 0 to 10 wt. %, based on total conductive metal paste composition.

The conductive metal paste applied in step (2) of the process of the present invention is a viscous composition, which may be prepared by mechanically mixing the particulate metal and the glass frit(s) with the organic vehicle. In an embodiment, the manufacturing method power mixing, a dispersion technique that is equivalent to the traditional roll milling, may be used; roll milling or other mixing technique can also be used.

The conductive metal paste can be used as such or may be diluted, for example, by the addition of additional organic solvent(s); accordingly, the weight percentage of all the other constituents of the conductive metal paste may be decreased.

The application viscosity of the conductive metal paste may be, for example, 20 to 400 Pa·s when it is measured at a spindle speed of 10 rpm and 25° C. by a utility cup using a Brookfield HBT viscometer and #14 spindle.

As already mentioned, the conductive metal paste is applied over the bottom set of thin conductive metal collector lines and to the holes of the silicon wafer to form a continuous metallization. The continuous metallization comprises the top set of thin conductive metal collector lines and the metallization of the inside of the holes, wherein the top set of thin conductive metal collector lines superimposes the bottom set of thin conductive metal collector lines. In an embodiment, the continuous metallization consists of the top set of thin conductive metal collector lines and the metallization of the inside of the holes, wherein the top set of thin conductive metal collector lines superimposes the bottom set of thin conductive metal collector lines. The bottom set of thin conductive metal collector lines not being part of said continuous metallization has no direct electric contact with the metallization of the inside of the holes but is indirectly electrically connected therewith via the top set of thin conductive metal collector lines.

With regard to the metallization of the inside of the holes the conductive metal paste may be applied in the form of a conductive metal layer (open hole) or in the form of a conductive metal plug (hole filled with conductive metal).

The method of conductive metal paste application may be printing, in particular, screen printing. The application is performed so as to superimpose the bottom set of thin conductive metal collector lines with the top set of thin conductive metal collector lines and to provide the inside of the holes with a metallization in one single application step, wherein the applied conductive metal paste forms a continuous metallization. As already mentioned, the continuous metallization comprises said top set of thin conductive metal collector lines and the metallization of the inside of the holes, i.e. the continuous metallization may consist of said top set of thin conductive metal collector lines and the metallization of the inside of the holes or, in an embodiment, it may consist of said top set of thin conductive metal collector lines, the metallization of the inside of the holes and also a metallization covering the narrow rims around the front edges of the holes, or, in another embodiment, it may consist of said top set of thin conductive metal collector lines, the metallization of the inside of the holes and also a metallization which covers a portion of the narrow rims around the front edges of the holes and thereby connects the top set of thin conductive metal collector lines and the metallization of the inside of the holes.

The thin conductive metal collector lines of the top set have a width of, for example, 50 to 150 μm and a dry layer thickness of, for example, 10 to 40 μm. The total dry layer thickness of the thin conductive metal collector lines (dry layer thickness of the conductive metal lines of the bottom set plus dry layer thickness of the conductive metal lines of the top set) is in the range of, for example, 20 to 60 μm.

In step (3) of the process of the present invention the conductive metal paste applied in step (2) is dried, for example, for a period of 1 to 100 minutes with the silicon wafer reaching a peak temperature in the range of 100 to 300° C. Drying can be carried out making use of, for example, belt, rotary or stationary driers, in particular, IR (infrared) belt driers.

In step (4) of the process of the present invention the dried conductive metal paste is fired to form the finished continuous metallization. The combination of the bottom set of thin conductive metal collector lines and the finished continuous metallization serves as emitter contacts and anodic back contacts of the MWT silicon solar cell. The firing of step (4) may be performed, for example, for a period of 1 to 5 minutes with the silicon wafer reaching a peak temperature in the range of 700 to 900° C. The firing can be carried out making use of, for example, single or multi-zone belt furnaces, in particular, multi-zone IR belt furnaces. The firing may happen in an inert gas atmosphere or in the presence of oxygen, for example, in the presence of air. During firing the organic substance including non-volatile organic material and the organic portion not evaporated during the drying may be removed, i.e. burned and/or carbonized, in particular, burned. The organic substance removed during firing includes organic solvent(s), optionally present organic polymer(s) and optionally present organic additive(s). At least in case of the particular embodiment of the process of the present invention there is a further process taking place during firing, namely sintering of glass frit with the particulate electrically conductive metal.

Firing may be performed as so-called cofiring together with silver back collector contacts applied from a back-side silver paste.

What is claimed is:

1. A process for the production of a MWT silicon solar cell comprising the steps:
(1) providing an n-type silicon wafer with (i) holes forming vias between the front-side and the back-side of the wafer, (ii) a p-type emitter extending over the entire front-side and the inside of the holes, (iii) an ARC layer on the front-side that leaves out the inside of the holes, and (iv) a front-side metallization in the form of a bottom set of thin conductive metal collector lines, said bottom set of thin conductive metal collector lines having no contact with the inside of the holes,
(2) applying a conductive metal paste over said bottom set of thin conductive metal collector lines and to the holes of the silicon wafer to form a continuous metallization which comprises a top set of thin conductive metal collector lines and a metallization of the inside of the holes,
(3) drying the applied conductive metal paste, and
(4) firing the dried conductive metal paste, whereby the wafer reaches a peak temperature of 700 to 900° C.,
wherein the top set of thin conductive metal collector lines superimposes the bottom set of thin conductive metal collector lines,
wherein the conductive metal paste has no or only poor fire-through capability and comprises (a) at least one particulate electrically conductive metal selected from the group consisting of silver, copper and nickel, and (b) an organic vehicle.

2. The process of claim 1, wherein the holes have a narrow rim around their front edges left out by the ARC layer and wherein the bottom set of thin conductive metal collector lines has no contact with said rims.

3. The process of claim 1, wherein the organic vehicle content is from 10 to 45 wt. %, based on total conductive metal paste composition.

4. The process of claim 1, wherein the electrically conductive metal is present in the conductive metal paste in a proportion of 50 to 92 wt. %.

5. The process of claim 1, wherein the electrically conductive metal is silver.

6. The process of claim 1, wherein the conductive metal paste comprises as component (c) at least one glass frit selected from the group consisting of (i) lead-free glass frits with a softening point temperature in the range of 550 to 611° C. and containing 11 to 33 wt. % of SiO₂, >0 to 7 wt. % of Al₂O₃ and 2 to 10 wt. % of B₂O₃ and (ii) lead-containing glass frits with a softening point temperature in the range of 571 to 636° C. and containing 53 to 57 wt. % of PbO, 25 to 29 wt. % of SiO₂, 2 to 6 wt. % of Al₂O₃ and 6 to 9 wt. % of B₂O₃.

7. The process of claim 6, wherein one or more of the lead-free glass frits contain 40 to 73 wt. % of Bi₂O₃.

8. The process of claim 6 or 7, wherein the total content of glass frit selected from the group consisting of types (i) and (ii) in the conductive metal paste is 0.25 to 8 wt. %.

9. The process of claim 1, wherein the conductive metal paste is applied as a conductive metal layer or as a conductive metal plug.

10. The process of claim 1, wherein the conductive metal paste is applied by printing.

11. The process of claim 1, wherein firing is performed as cofiring together with a back-side silver paste that has been applied to the back-side to form silver back collector contacts.

12. A MWT silicon solar cell made by the process of claim 1.
